(19) United States
(12) Patent Application Publication
(10) Pub. No.: US 2025/0223701 A1
(43) Pub. Date: Jul. 10, 2025

(54) SUBSTRATE-PROCESSING APPARATUS AND SUBSTRATE-PROCESSING METHOD

(71) Applicant: Tokyo Electron Limited, Tokyo (JP)

(72) Inventors: Takehiro FUKADA, Iwate (JP); Yasushi TAKEUCHI, Iwate (JP); Yasutomo KIMURA, Iwate (JP)

(21) Appl. No.: 19/000,910

(22) Filed: Dec. 24, 2024

(30) Foreign Application Priority Data
Jan. 10, 2024 (JP) 2024-001933

(51) Int. Cl. C23C 16/458

(52) U.S. Cl. CPC C23C 16/4584

(57) ABSTRACT

A substrate-processing apparatus includes a vacuum chamber; a rotation table provided in the vacuum chamber; a stage that is rotatable relative to the rotation table and includes a recess in which a substrate is to be placed; and a controller including a memory and a processor connected to the memory. A rotation shaft of the stage is provided at a position that is shifted from a center of the rotation table in a radial direction. The processor is configured to perform a film-forming process of forming a film on the substrate placed in the recess, while maintaining a state in which the rotation table and the stage are being rotated in opposite directions.

### CROSS-REFERENCE TO RELATED APPLICATIONS

This application is based upon and claims priority to Japanese Patent Application No. 2024-001933, filed on Jan. 10, 2024, the entire contents of which are incorporated herein by reference.

### BACKGROUND

### 1. Field of the Invention

The present disclosure relates to a substrate-processing apparatus and a substrate-processing method.

### 2. Description of the Related Art

An apparatus configured to process, in a process chamber, a substrate placed on a rotation table while causing the substrate to spin and revolve, is known. See, for example, Japanese Patent Application Publication No. 2020-119921.

### SUMMARY

A substrate-processing apparatus according to an aspect of the present disclosure includes: a vacuum chamber; a rotation table provided in the vacuum chamber; a stage that is rotatable relative to the rotation table and includes a recess in which a substrate is to be placed; and a controller including a memory and a processor connected to the memory. A rotation shaft of the stage is provided at a position that is shifted from a center of the rotation table in a radial direction of the rotation table. The processor is configured to perform a film-forming process of forming a film on the substrate placed in the recess, while maintaining a state in which the rotation table and the stage are being rotated in opposite directions.

### BRIEF DESCRIPTION OF THE DRAWINGS

FIG. 1 is a cross-sectional view illustrating a substrate-processing apparatus according to an embodiment of the present disclosure;

FIG. 2 is a plan view illustrating a configuration of the interior of a vacuum chamber of the substrate-processing apparatus of FIG. 1;

FIG. 3 is a perspective view illustrating a configuration of a rotation table and a stage of the substrate-processing apparatus of FIG. 1;

FIG. 4 is a cross-sectional view illustrating a configuration of the interior of a housing box of the substrate-processing apparatus of FIG. 1;

FIG. 5 is a cross-sectional view illustrating a configuration of the stage of the substrate-processing apparatus of FIG. 1;

FIG. 6 is a diagram (1) illustrating a mechanism in which particles are generated;

FIG. 7 is a diagram (2) illustrating a mechanism in which particles are generated;

FIG. 8 is a diagram (3) illustrating a mechanism in which particles are generated;

FIG. 9 is a flowchart illustrating a substrate-processing method according to an embodiment of the present disclosure; and

FIG. 10 is a chart illustrating results obtained by measuring the number of particles.

### DETAILED DESCRIPTION OF THE DISCLOSURE

The present disclosure provides a technique capable of suppressing adhesion of particles onto a substrate.

Hereinafter, non-limiting embodiments of the present disclosure will be described with reference to the drawings. In all of the drawings, the same or corresponding members or parts will be denoted with the same or corresponding reference numerals, and duplicate description thereof will be omitted.

### [Substrate-Processing Apparatus]

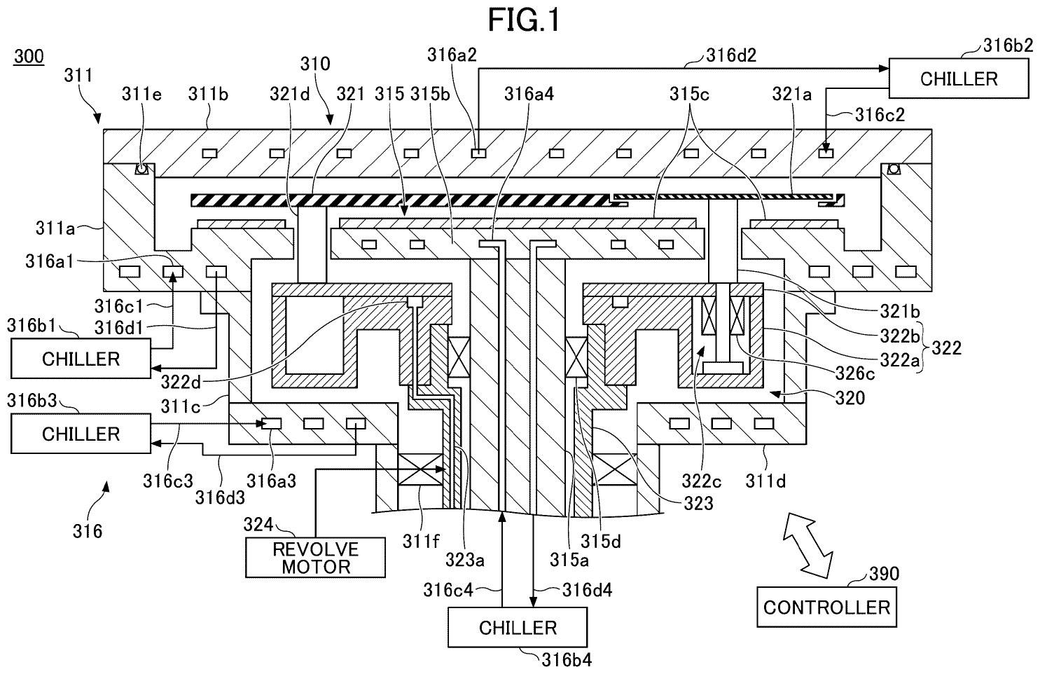

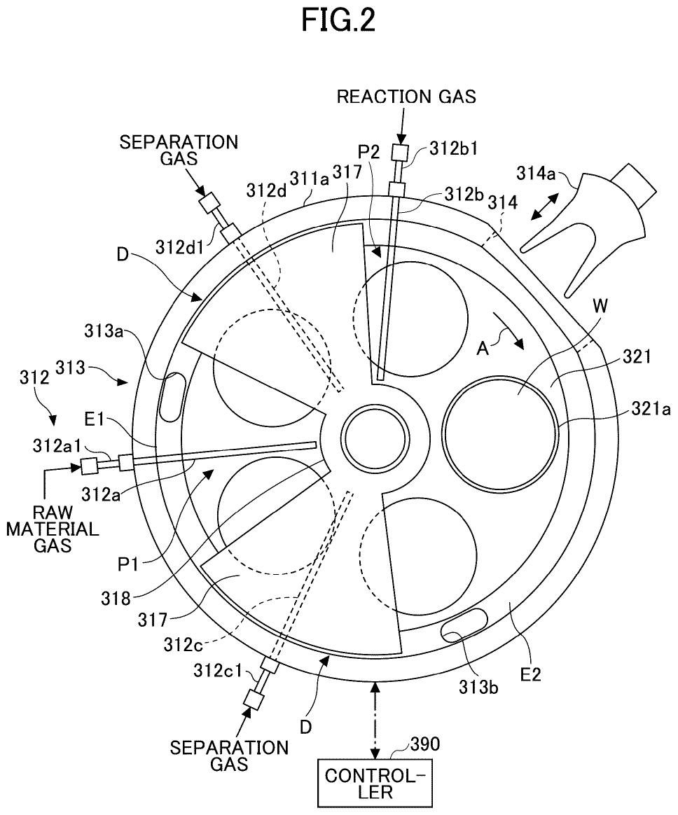

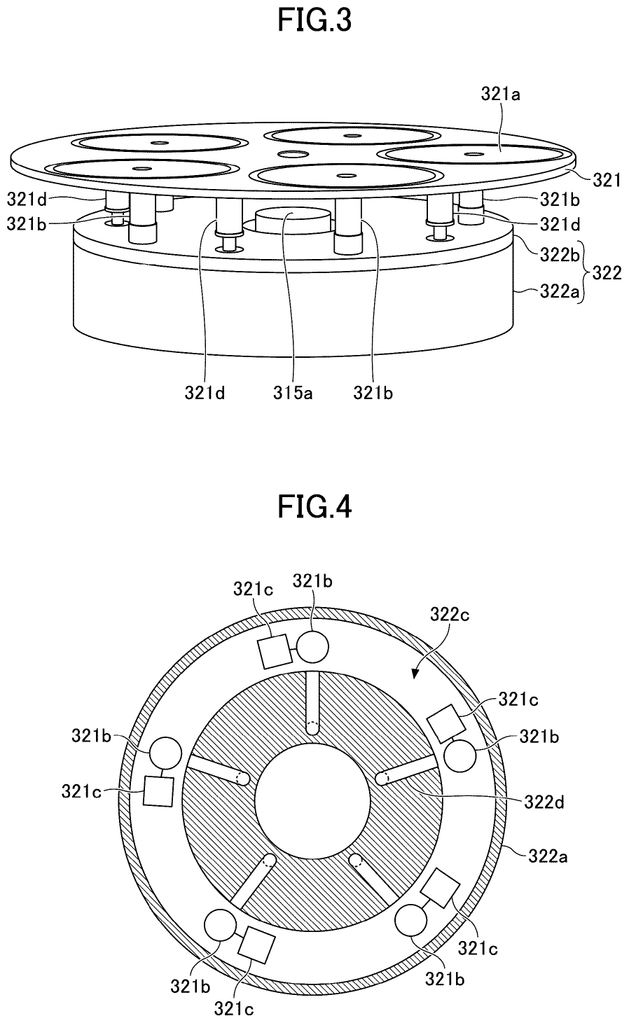

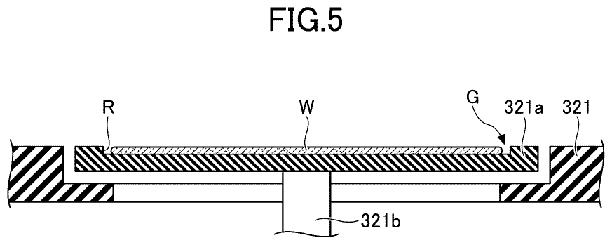

A substrate-processing apparatus 300 according to an embodiment of the present disclosure will be described with reference to FIGS. 1 to 5. FIG. 1 is a cross-sectional view illustrating the substrate-processing apparatus 300 according to the embodiment. FIG. 2 is a plan view illustrating a configuration of the interior of a vacuum chamber 311 of the substrate-processing apparatus 300 of FIG. 1. In FIG. 2, illustration of a top plate 311b is omitted for the sake of convenience. FIG. 3 is a perspective view illustrating a configuration of a rotation table 321 and a stage 321a of the substrate-processing apparatus 300 of FIG. 1. FIG. 4 is a cross-sectional view illustrating a configuration of the interior of a housing box 322 of the substrate-processing apparatus 300 of FIG. 1. FIG. 5 is a cross-sectional view illustrating a configuration of the stage 321a of the substrate-processing apparatus 300 of FIG. 1.

The substrate-processing apparatus 300 includes a processor 310, a rotation driver 320, and a controller 390.

The processor 310 is configured to perform a film-forming process of forming a film on the substrate W. The substrate W is, for example, a semiconductor wafer. The processor 310 includes the vacuum chamber 311, a gas inlet 312, a gas outlet 313, a transfer port 314, a heater 315, and a cooler 316.

The vacuum chamber 311 is a chamber that can be reduced in internal pressure. The vacuum chamber 311 has a substantially circular planar flat shape, and is configured to house a plurality of substrates W in the vacuum chamber 311. The vacuum chamber 311 includes a body 311a, the top plate 311b, a side wall 311c, and a bottom plate 311d (FIG. 1). The body 311a has a cylindrical shape. The top plate 311b is airtightly detachably disposed on the top surface of the body 311a via a sealing 311e. The side wall 311c is connected to the bottom surface of the body 311a, and has a cylindrical shape. The bottom plate 311d is disposed airtightly with respect to the bottom surface of the side wall 311c.

The gas inlet 312 includes a raw material gas nozzle 312a, a reaction gas nozzle 312b, and separation gas nozzles 312c and 312d (FIG. 2). The raw material gas nozzle 312a, the reaction gas nozzle 312b, and the separation gas nozzles 312c and 312d are disposed over the rotation table 321 at intervals in a circumferential direction of the vacuum chamber 311 (a direction indicated by an arrow A in FIG. 2). In the illustrated example, the separation gas nozzle 312c, the raw material gas nozzle 312a, the separation gas nozzle 312d, and the reaction gas nozzle 312b are arranged in this order in a clockwise direction from the transfer port 314 (a rotation direction of the rotation table 321). Gas inlet ports 312a1, 312b1, 312c1, and 312d1 (FIG. 2), which are ends of the raw material gas nozzle 312a, the reaction gas nozzle 312b, and the separation gas nozzles 312c and 312d, are fixed to the outer wall of the body 311a. The raw material gas nozzle 312a, the reaction gas nozzle 312b, and the separation gas nozzles 312c and 312d are introduced into the vacuum chamber 311 from the outer wall of the vacuum chamber 311, and are attached so as to extend horizontally with respect to the rotation table 321 along the radial direction of the body 311a. The raw material gas nozzle 312a, the reaction gas nozzle 312b, and the separation gas nozzles 312c and 312d are formed of quartz or the like.

The raw material gas nozzle 312a is connected to a raw material gas supply source (not illustrated) through a tube, a flow rate controller, and the like (not illustrated). As a raw material gas, a silicon-containing gas, a metal-containing gas, or the like can be used. The raw material gas nozzle 312a is provided with a plurality of discharge holes (not illustrated) that are opened toward the rotation table 321 and are arranged at intervals along a longitudinal direction of the raw material gas nozzle 312a. A region below the raw material gas nozzle 312a serves as a raw material gas adsorption region P1 where the raw material gas is adsorbed to the substrate W.

The reaction gas nozzle 312b is connected to a reaction gas supply source (not illustrated) through a tube, a flow rate controller, and the like (not illustrated). As a reaction gas, an oxidizing gas, a nitriding gas, or the like can be used. The reaction gas nozzle 312b is provided with a plurality of discharge holes (not illustrated) that are opened toward the rotation table 321 and are arranged at intervals along a longitudinal direction of the reaction gas nozzle 312b. A region below the reaction gas nozzle 312b serves as a reaction gas supply region P2 where the raw material gas, adsorbed onto the substrate W in the raw material gas adsorption region P1, is caused to undergo oxidizing or nitriding.

The separation gas nozzles 312c and 312d are each connected to a separation gas supply source (not illustrated) through a tube, a flow rate control valve, and the like (not illustrated). As a separation gas, an inert gas, such as argon (Ar) gas, nitrogen (N₂) gas, or the like can be used. The separation gas nozzles 312c and 312d are each provided with a plurality of discharge holes (not illustrated) that are opened toward the rotation table 321 and are arranged at intervals along the longitudinal direction of the separation gas nozzles 312c and 312d.

As illustrated in FIG. 2, two projecting portions 317 are provided in the vacuum chamber 311. The projecting portions 317 are attached to the back surface of the top plate 311b so as to project toward the rotation table 321, in order to form separation regions D along with the separation gas nozzles 312c and 312d. The projecting portions 317 each have a fan-like planar shape in which the outermost portion is cut into an arc shape and the inner arc is connected to a projection 318. The projecting portions 317 are disposed such that the outer arcs are along the inner wall of the body 311a of the vacuum chamber 311.

The gas outlet 313 includes a first gas outlet 313a and a second gas outlet 313b (FIG. 2). The first gas outlet 313a is formed at the bottom of a first gas exhaust region E1 that is in communication with the raw material gas adsorption region P1. The second gas outlet 313b is formed at the bottom of a second gas exhaust region E2 that is in communication with the reaction gas supply region P2. The first gas outlet 313a and the second gas outlet 313b are connected to a gas exhaust device (not illustrated) through a gas exhaust tube (not illustrated).

The transfer port 314 is provided at the side wall of the vacuum chamber 311 (FIG. 2). Through the transfer port 314, transfer of the substrate W is performed between the rotation table 321 in the vacuum chamber 311 and a transfer arm 314a outside the vacuum chamber 311.

The transfer port 314 is opened and closed by a gate valve (not illustrated).

The heater 315 includes a fixed shaft 315a, a heating element support 315b, and a heating element 315c (FIG. 1).

The fixed shaft 315a has a cylindrical shape having a center axis that passes through the center of the vacuum chamber 311. The fixed shaft 315a is provided inside a rotation shaft 323 so as to penetrate through the bottom plate 311d of the vacuum chamber 311. A sealing 315d is provided between the outer wall of the fixed shaft 315a and the inner wall of the rotation shaft 323. Thus, the rotation shaft 323 rotates with respect to the fixed shaft 315a while maintaining an airtight state of the interior of the vacuum chamber 311. The sealing 315d includes a magnetic fluid sealing or the like.

The heating element support 315b is fixed to the top of the fixed shaft 315a, and has a disk shape. The heating element support 315b is configured to support the heating element 315c.

The heating element 315c is provided on the top surface of the heating element support 315b. The heating element 315c may be provided on the body 311a in addition to on the top surface of the heating element support 315b. The heating element 315c is configured to generate heat by supply of power from a power supply (not illustrated) and heat the substrate W.

The cooler 316 includes fluid flow paths 316a1 to 316a4, chillers 316b1 to 316b4, inlet tubes 316c1 to 316c4, and outlet tubes 316d1 to 316d4. The fluid flow paths 316a1, 316a2, 316a3, and 316a4 are formed inside the body 311a, the top plate 311b, the bottom plate 311d, and the heating element support 315b, respectively. The chillers 316b1 to 316b4 are configured to output a temperature-controlled fluid. The temperature-controlled fluid output from the chillers 316b1 to 316b4 is caused to flow and circulate through the inlet tubes 316c1 to 316c4, the fluid flow paths 316a1 to 316a4, and the outlet tubes 316d1 to 316d4, in this order. Thus, the body 311a, the top plate 311b, the bottom plate 311d, and the heating element support 315b are adjusted in temperature. As the temperature-controlled fluid, for example, water or fluorine-based fluids, such as GALDEN (registered trademark), can be used.

The rotation driver 320 includes the rotation table 321, the housing box 322, the rotation shaft 323, and a revolve motor 324 (i.e., a motor for revolving).

The rotation table 321 is provided in the vacuum chamber 311, and has a rotation center at the center of the vacuum chamber 311. For example, the rotation table 321 has a disk shape and is formed of quartz. A plurality of (e.g., five) stages 321a are provided on the top surface of the rotation table 321 along a rotation direction (a circumferential direction) of the rotation table 321. The rotation table 321 is connected to the housing box 322 via a connector 321d.

The stages 321a each have a disk shape that is slightly larger than the substrate W. The stage 321a is formed of quartz or the like. A recess R is formed at the top surface of the stage 321a. The recess R has a circular shape in a plan view. The substrate W is placed in the recess R. The recess R has an inner diameter that is slightly larger than the diameter of the substrate W. Therefore, there is a gap G between the inner side surface of the recess R and the outer periphery of the substrate W. The recess R has a depth that is substantially equal to or larger than the thickness of the substrate W. Thus, when the substrate W is placed in the recess R, the top surface of the substrate W is the same in height as the top surface of a region of the stage 321a where the substrate W is not placed. Alternatively, the top surface of the substrate W is lower than the top surface of a region of the stage 321a where the substrate W is not placed. Each stage 321a is connected to a spin motor 321c (i.e., a motor for spinning or rotating) via a spinning shaft 321b, and is configured to be rotatable relative to the rotation table 321.

The spinning shaft 321b connects the bottom surface of the stage 321a to the spin motor 321c housed in the housing box 322, and is configured to transmit a driving force of the spin motor 321c to the stage 321a. The spinning shaft 321b is configured to be rotatable about a rotation center that is the center of the stage 321a. The spinning shaft 321b is provided at a position that is shifted from the center of the rotation table 321 in a radial direction of the rotation table 321. The spinning shaft 321b is provided so as to penetrate through a ceiling 322b of the housing box 322 and the rotation table 321. A sealing 326c is provided in a through-hole of the ceiling 322b of the housing box 322, thereby maintaining an airtight state of the interior of the housing box 322. The sealing 326c includes a magnetic fluid sealing or the like.

The spin motor 321c is configured to rotate the stage 321a relative to the rotation table 321 via the spinning shaft 321b, thereby causing the substrate W to spin. The spin motor 321c may be a servomotor or the like.

The connector 321d connects, for example, the bottom surface of the rotation table 321 to the top surface of the housing box 322. The connector 321d is provided, for example, in two or more along the circumferential direction of the rotation table 321.

The housing box 322 is provided below the rotation table 321 in the vacuum chamber 311. The housing box 322 is connected to the rotation table 321 via the connector 321d, and is configured to be rotatable integrally with the rotation table 321. The housing box 322 may be configured to rise or lower in the vacuum chamber 311 in a rising and lowering mechanism (not illustrated). The housing box 322 includes a body 322a and the ceiling 322b.

The body 322a is formed in a recessed shape in a cross-sectional view, and is formed in a ring shape along the rotation direction of the rotation table 321.

The ceiling 322b is provided on the top surface of the body 322a so as to cover an opening of the body 322a, the opening being formed in a recessed shape in a cross-sectional view. Thus, the body 322a and the ceiling 322b form a housing 322c isolated from the interior of the vacuum chamber 311.

The housing 322c is formed in a rectangular shape in a cross-sectional view, and is formed in a ring shape along the rotation direction of the rotation table 321. The housing 322c houses the spin motor 321c. The body 322a is provided with a communication path 322d for communication between the housing 322c and the exterior of the substrate-processing apparatus 300. Thus, air is introduced into the housing 322c from the exterior of the substrate-processing apparatus 300, and the interior of the housing 322c is cooled and maintained to be the atmospheric pressure.

The rotation shaft 323 is fixed to the bottom of the housing box 322. The rotation shaft 323 is provided so as to penetrate through the bottom plate 311d of the vacuum chamber 311. The rotation shaft 323 transmits a driving force of the revolve motor 324 to the rotation table 321 and the housing box 322, thereby integrally rotating the rotation table 321 and the housing box 322. A sealing 311f is provided in a through-hole of the bottom plate 311d of the vacuum chamber 311, thereby maintaining an airtight state of the interior of the vacuum chamber 311. The sealing 311f includes a magnetic fluid sealing or the like.

A through-hole 323a is formed inside the rotation shaft 323. The through-hole 323a is connected to the communication path 322d of the housing box 322, and functions as a fluid flow path for introduction of air into the housing box 322. Also, the through-hole 323a functions as a wiring duct for introduction, into the housing box 322, of a power line and a signal line configured to drive the spin motor 321c. For example, the through-hole 323a is provided in the same number as the number in which the spin motor 321c is provided.

The controller 390 is configured to control each component of the substrate-processing apparatus 300. The controller 390 is a computer or the like. A program of a computer, configured to move each component of the substrate-processing apparatus 300, is stored in a storage medium. The storage medium may be, for example, a flexible disk, a compact disc, a hard disk, a flash memory, a DVD, or the like.

The controller 390 is configured to perform a film-forming process of forming a film on the substrate W placed in the recess R, while maintaining a state in which the rotation table 321 and the stage 321a are being rotated in opposite directions.

For example, the controller 390 rotates the rotation table 321 in a first rotation direction, and rotates the stage 321a in a second rotation direction that is opposite to the first rotation direction. For example, the first rotation direction is a clockwise direction, and the second rotation direction is a counterclockwise direction. The first rotation direction may be a counterclockwise direction, and the second rotation direction may be a clockwise direction. The rotation speed of the rotation table 321 is, for example, equal to or higher than the speed at which the substrate W placed in the recess R moves relative to the recess R in response to rotation of the rotation table 321. The rotation speed of the rotation table 321 is, for example, 40 rpm or higher and 120 rpm or lower. The rotation speed of the stage 321a may be lower than the rotation speed of the rotation table 321. The rotation speed of the stage 321a is, for example, 1 rpm or higher and 10 rpm or lower.

For example, the controller 390 performs control not to change the rotation direction of the rotation table 321 and the rotation direction of the stage 321a during the film-forming process. For example, the controller 390 performs control to maintain, throughout the film-forming process, a state in which the rotation table 321 is being rotated in the first rotation direction and the stage 321a is being rotated in the second rotation direction.

The controller 390 may perform control to change the rotation direction of the rotation table 321 and the rotation direction of the stage 321a during the film-forming process. For example, the controller 390 starts a film-forming process while maintaining, during a first period, i.e. an initial period of the film-forming process, a state in which the rotation table 321 is being rotated in the first rotation direction and the stage 321a is being rotated in the second rotation direction. Next, at the time the first period has passed, the controller 390 switches the rotation direction of the rotation table 321 from the first rotation direction to the second rotation direction, and switches the rotation direction of the stage 321a from the second rotation direction to the first rotation direction. Next, the controller 390 continues the film-forming process while maintaining, during a second period after the first period, a state in which the rotation table 321 is being rotated in the second rotation direction and the stage 321a is being rotated in the first rotation direction. The controller 390 ends the film-forming process after the second period has passed. However, after the second period has passed, the controller 390 may switch the rotation direction of the rotation table 321 and the rotation direction of the stage 321a again, and continue the film-forming process.

The controller 390 may perform control to change the rotation speed of at least one of the rotation table 321 or the stage 321a during the film-forming process.

As described above, according to the substrate-processing apparatus 300 according to the embodiment, the controller 390 is configured to perform the film-forming process of forming a film on the substrate W placed in the recess R, while maintaining the state in which the rotation table 321 and the stage 321a are being rotated in opposite directions. In this case, it is possible to reduce an impact of collision between the inner side surface of the recess R and the outer periphery of the substrate W. Therefore, generation of particles due to collision can be suppressed. As a result, adhesion of particles onto the substrate W can be suppressed.

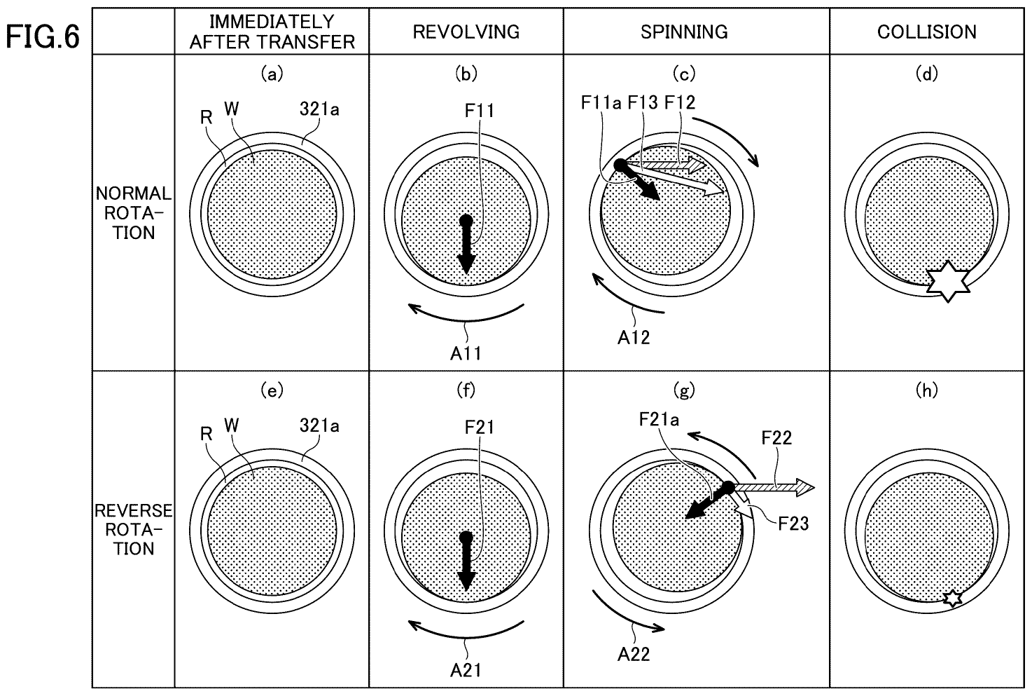

A mechanism in which particles are generated will be described with reference to FIGS. 6 to 8. FIGS. 6 to 8 are diagrams illustrating the mechanism in which particles are generated.

In FIG. 6, (a) to (h) illustrate cases in which the stage 321a is located in the six o'clock (6:00) direction of the rotation table 321. In FIG. 6, (a) to (d) illustrate a movement of the substrate W in the recess R when the rotation table 321 and the stage 321a are rotated in the same direction (hereinafter referred to as “normal rotation”). In FIG. 6, (e) to (h) illustrate a movement of the substrate W in the recess R when the rotation table 321 and the stage 321a are rotated in opposite directions (hereinafter referred to as “reverse rotation”).

In the normal rotation, when the substrate W is transferred to the recess R of the stage 321a, the substrate W is placed in a center area of the recess R as illustrated in (a) of FIG. 6. Next, when the rotation table 321 is rotated clockwise (the substrate W is revolved clockwise) along a direction indicated by an arrow A11 in (b) of FIG. 6, a centrifugal force F11 in a direction away from the rotation center of the rotation table 321 is applied to the substrate W. Therefore, the substrate W moves in the recess R in the 6:00 direction of the stage 321a, and the outer periphery of the substrate W contacts the inner side surface of the recess R. Further, as indicated by an arrow A12 in (c) of FIG. 6, when the stage 321a is rotated clockwise (the substrate W is spun clockwise), i.e., in the rotation direction the same as that of the rotation table 321, the contact position between the inner side surface of the recess R and the outer periphery of the substrate W is moved clockwise, for example, from the six o'clock (6:00) direction to the ten o'clock (10:00) direction. At this time, as illustrated in (c) of FIG. 6, an inertial force F12 generated by the rotation of the rotation table 321 is applied to the substrate W. Therefore, as illustrated in (c) of FIG. 6, a resultant force F13 of the inertial force F12 and a component F11a of the centrifugal force F11, decomposed in a direction away from the inner side surface of the recess R, is applied to the substrate W. The direction of the resultant force F13 is a direction away from the inner side surface of the recess R at the contact position between the inner side surface of the recess R and the outer periphery of the substrate W. As a result, as illustrated in (d) of FIG. 6, the substrate W moves in the recess R due to the resultant force F13, and the outer periphery of the substrate W collides on the inner side surface of the recess R, for example, at a position in the five o'clock (5:00) direction of the stage 321a. At this time, the impact of collision becomes large.

In the reverse rotation, when the substrate W is transferred to the recess R of the stage 321a, the substrate W is placed in a center area of the recess R as illustrated in (e) of FIG. 6. Next, when the rotation table 321 is rotated clockwise (the substrate W is revolved clockwise) along a direction indicated by an arrow A21 in (f) of FIG. 6, a centrifugal force F21 in a direction away from the rotation center of the rotation table 321 is applied to the substrate W. Therefore, the substrate W moves in the recess R in the 6:00 direction of the stage 321a, and the outer periphery of the substrate W contacts the inner side surface of the recess R. Further, as indicated by an arrow A22 in (g) of FIG. 6, when the stage 321a is rotated counterclockwise, i.e., in the rotation direction opposite to that of the rotation table 321, the contact position between the inner side surface of the recess R and the outer periphery of the substrate W is moved, for example, from the six o'clock (6:00) direction to the two o'clock (2:00) direction. At this time, as illustrated in (g) of FIG. 6, an inertial force F22 generated by the rotation of the rotation table 321 is applied to the substrate W. Therefore, as illustrated in (g) of FIG. 6, a resultant force F23 of the inertial force F22 and a component F21a of the centrifugal force F21, decomposed in a direction away from the inner side surface of the recess R, is applied to the substrate W. The direction of the resultant force F23 is a direction along the inner side surface of the recess R at the contact position between the inner side surface of the recess R and the outer periphery of the substrate W. The magnitude of the resultant force F23 is smaller than that of the resultant force F13. As a result, as illustrated in (h) of FIG. 6, it is possible to reduce an impact of collision between the inner side surface of the recess R and the outer periphery of the substrate W when the substrate W moves in the recess R due to the resultant force F23.

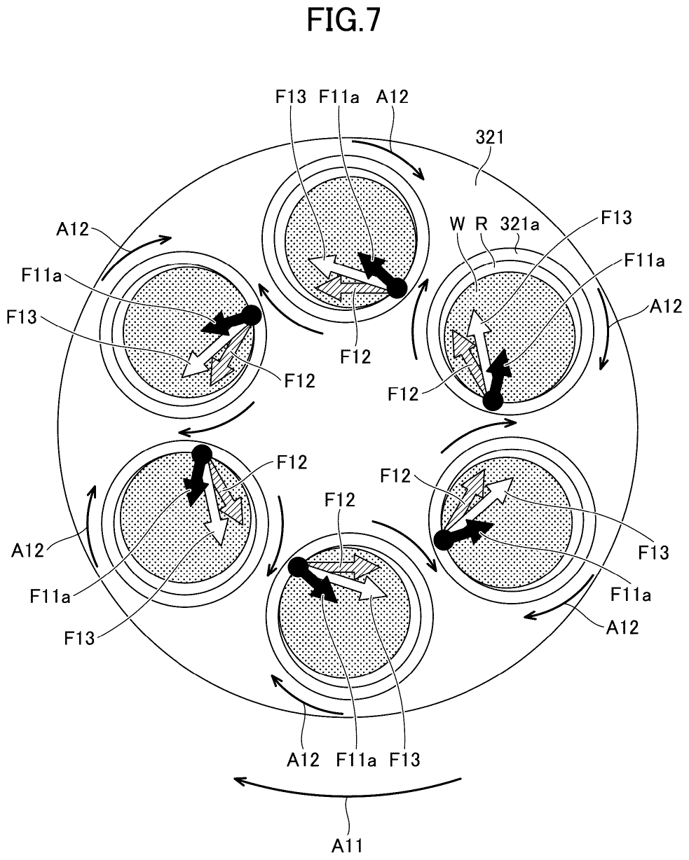

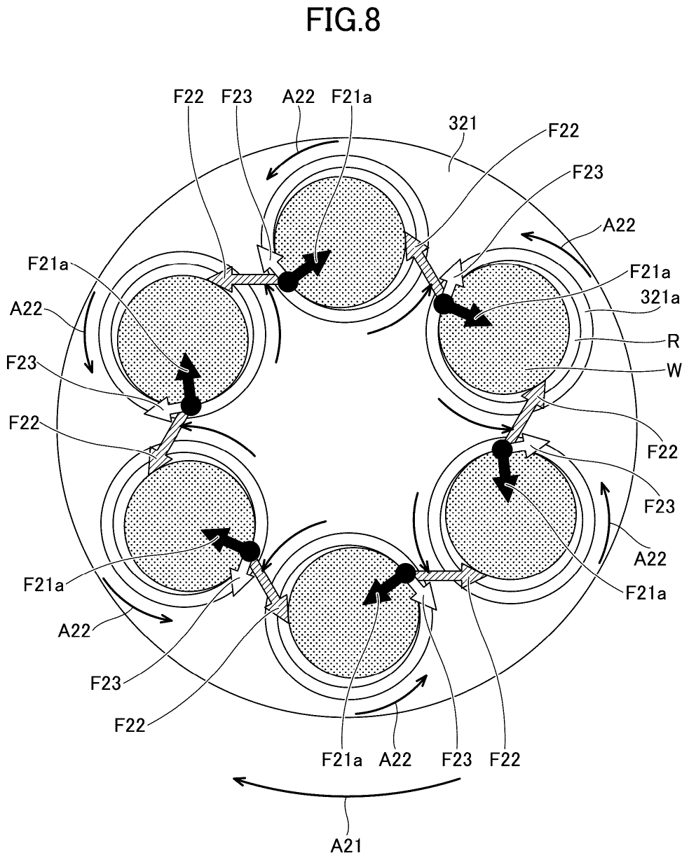

FIGS. 7 and 8 are diagrams illustrating a case in which six stages 321a are provided along the rotation direction of the rotation table 321, and a force is applied to the substrate W placed on each of the stages 321a. FIG. 7 illustrates the case of the normal rotation, and FIG. 8 illustrates the case of the reverse rotation.

As illustrated in FIG. 7, similar to the substrate W placed on the stage 321a located in the 6:00 direction of the rotation table 321, the same applies to the substrates W placed on the stages 321a located in the zero o'clock (0:00), two o'clock (2:00), four o'clock (4:00), eight o'clock (8:00), and ten o'clock (10:00) directions of the rotation table 321. That is, the resultant force F13 in the direction away from the inner side surface of the recess R is applied to the substrates W placed on the stages 321a located in the 0:00, 2:00, 4:00, 8:00, and 10:00 directions of the rotation table 321 at the contact position between the inner side surface of the recess R and the outer periphery of the substrate W. Therefore, the substrate W moves in the recess R due to the resultant force F13, and the outer periphery of the substrate W collides on the inner side surface of the recess R. At this time, the impact of collision becomes large.

As illustrated in FIG. 8, similar to the substrate W placed on the stage 321a located in the 6:00 direction of the rotation table 321, the same applies to the substrates W placed on the stages 321a located in the 0:00, 2:00, 4:00, 8:00, and 10:00 directions of the rotation table 321. That is, the resultant force F23 in the direction along the inner side surface of the recess R is applied to the substrates W placed on the stages 321a located in the 0:00, 2:00, 4:00, 8:00, and 10:00 directions of the rotation table 321 at the contact position between the inner side surface of the recess R and the outer periphery of the substrate W. The magnitude of the resultant force F23 is smaller than that of the resultant force F13. Therefore, it is possible to reduce an impact of collision between the inner side surface of the recess R and the outer periphery of the substrate W when the substrate W moves in the recess R due to the resultant force F23.

### [Substrate-Processing Method]

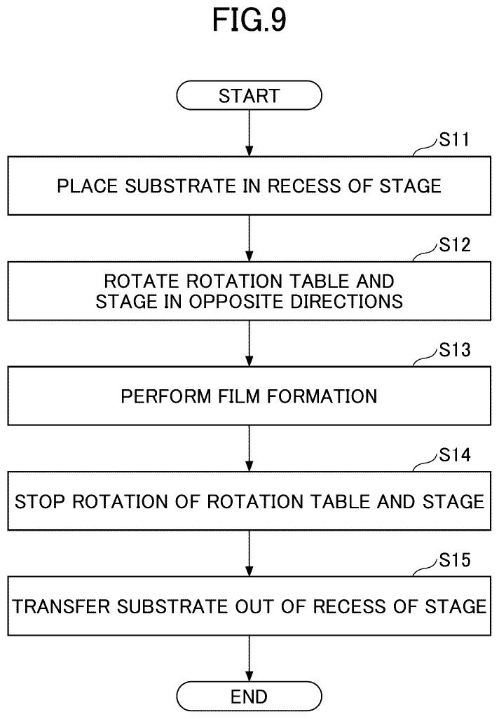

A substrate-processing method according to an embodiment of the present disclosure will be described with reference to FIG. 9. The substrate-processing method according to the embodiment is, for example, performed by the controller 390 that controls a movement of each component of the substrate-processing apparatus 300. FIG. 9 is a flowchart illustrating the substrate-processing method according to the embodiment. The substrate-processing method illustrated in FIG. 9 includes steps S11 to S15.

In step S11, the controller 390 performs a process of placing the substrate W in each of the recesses R of the stages 321a. Specifically, first, the revolve motor 324 rotates the rotation table 321, thereby moving one of the stages 321a to a position corresponding to the transfer port 314. Next, the controller 390 opens a gate valve. Next, the transfer arm 314a places the substrate W in the recess R of the stage 321a located at the position corresponding to the transfer port 314. Next, the revolve motor 324 rotates the rotation table 321, thereby moving another one of the stages 321a to the position corresponding to the transfer port 314. Next, the transfer arm 314a places the substrate W in the recess R of the stage 321a located at the position corresponding to the transfer port 314. In a similar manner, the substrate W is placed in the recess R of the rest of the stages 321a.

Step S12 is performed after step S11. In step S12, the controller 390 controls the revolve motor 324 and the spin motor 321c, thereby rotating the rotation table 321 and the stage 321a in opposite directions. For example, the controller 390 rotates the rotation table 321 in a first rotation direction, and rotates the stage 321a in a second rotation direction that is opposite to the first rotation direction. The rotation speed of the rotation table 321 is, for example, 40 rpm or higher and 120 rpm or lower. The rotation speed of the stage 321a is, for example, 1 rpm or higher and 10 rpm or lower.

Step S13 is performed after step S12. In step S13, the controller 390 controls the processor 310, thereby performing the film-forming process on the substrate W. For example, in a state in which a separation gas is supplied to the separation regions D from the separation gas nozzles 312c and 312d, the controller 390 supplies a raw material gas from the raw material gas nozzle 312a to the raw material gas adsorption region P1, and supplies a reaction gas from the reaction gas nozzle 312b to the reaction gas supply region P2. When the substrate W placed on the stage 321a of the rotation table 321 repeatedly passes through the raw material gas adsorption region P1 and the reaction gas supply region P2, a film is deposited on the surface of the substrate W through atomic layer deposition (ALD). After deposition of a film having a desired film thickness, the controller 390 stops the supply of the separation gas from the separation gas nozzles 312c and 312d, the supply of the raw material gas from the raw material gas nozzle 312a, and the supply of the reaction gas from the reaction gas nozzle 312b.

In step S13, for example, the controller 390 performs control not to change the rotation direction of the rotation table 321 and the rotation direction of the stage 321a during the film-forming process. For example, the controller 390 performs control to maintain, throughout the film-forming process, a state in which the rotation table 321 is being rotated in the first rotation direction and the stage 321a is being rotated in the second rotation direction.

In step S13, the controller 390 may perform control to change the rotation direction of the rotation table 321 and the rotation direction of the stage 321a during the film-forming process. For example, the controller 390 starts a film-forming process while maintaining, during a first period, i.e., an initial period of the film-forming process, a state in which the rotation table 321 is being rotated in the first rotation direction and the stage 321a is being rotated in the second rotation direction. Next, at the time the first period has passed, the controller 390 switches the rotation direction of the rotation table 321 from the first rotation direction to the second rotation direction, and switches the rotation direction of the stage 321a from the second rotation direction to the first rotation direction. Next, the controller 390 continues the film-forming process while maintaining, during a second period after the first period, a state in which the rotation table 321 is being rotated in the second rotation direction and the stage 321a is being rotated in the first rotation direction. The controller 390 ends the film-forming process after the second period has passed. However, after the second period has passed, the controller 390 may switch the rotation direction of the rotation table 321 and the rotation direction of the stage 321a again, and continue the film-forming process.

In step S13, the controller 390 may perform control to change the rotation speed of at least one of the rotation table 321 or the stage 321a during the film-forming process.

Step S14 is performed after step S13. In step S14, the controller 390 controls the revolve motor 324 and the spin motor 321c, thereby stopping the rotation of the rotation table 321 and the rotation of the stage 321a.

Step S15 is performed after step S14. In step S15, the controller 390 performs a process of transferring the substrate W from the recess R of each of the stages 321a to the exterior of the vacuum chamber 311. Specifically, first, the revolve motor 324 rotates the rotation table 321, thereby moving one of the stages 321a to a position corresponding to the transfer port 314. Next, the spin motor 321c rotates the stage 321a moved to the position corresponding to the transfer port 314 and causes the substrate W placed on the stage 321a to spin, thereby performing positioning of the substrate W in the rotation direction of the stage 321a. Next, the controller 390 opens a gate valve. Next, the transfer arm 314a transfers, to the exterior of the vacuum chamber 311, the substrate W placed in the recess R of the stage 321a located at the position corresponding to the transfer port 314. Next, the revolve motor 324 rotates the rotation table 321, thereby moving another one of the stages 321a to the position corresponding to the transfer port 314. Next, the spin motor 321c rotates the stage 321a moved to the position corresponding to the transfer port 314 and causes the substrate W placed on the stage 321a to spin, thereby performing positioning of the substrate W in the rotation direction of the stage 321a. Next, the transfer arm 314a transfers to the exterior of the vacuum chamber 311, the substrate W placed in the recess R of the stage 321a located at the position corresponding to the transfer port 314. In a similar manner, the substrate W placed in the recess R of the rest of the stages 321a is transferred to the exterior of the vacuum chamber 311.

As described above, according to the substrate-processing method according to the embodiment, the controller 390 is configured to perform the film-forming process of forming a film on the substrate W placed in the recess R, while maintaining the state in which the rotation table 321 and the stage 321a are being rotated in opposite directions. In this case, it is possible to reduce an impact of collision between the inner side surface of the recess R and the outer periphery of the substrate W. Therefore, generation of particles due to collision can be suppressed. As a result, adhesion of particles onto the substrate W can be suppressed.

### Examples

In an Example, the substrate-processing method according to the embodiment was performed using the substrate-processing apparatus 300. In the Example, the film-forming process of forming a film on the substrate W placed in the recess R was performed while maintaining a state in which the rotation table 321 and the stage 321a were being rotated in opposite directions. Specifically, the rotation direction of the rotation table 321 was a clockwise direction, and the rotation direction of the stage 321a was a counterclockwise direction.

As a Comparative Example, the substrate-processing apparatus 300 was used to perform a film-forming process of forming a film on the substrate W placed in the recess R, while maintaining a state in which the rotation table 321 and the stage 321a were being rotated in the same direction. Specifically, the rotation direction of the rotation table 321 was a clockwise direction, and the rotation direction of the stage 321a was a clockwise direction. The Comparative Example is the same as the Example except that the rotation table 321 and the stage 321a were rotated in the same direction.

Next, for the Example and the Comparative Example, the number of particles adhered to the substrate W after completion of the film-forming process was evaluated.

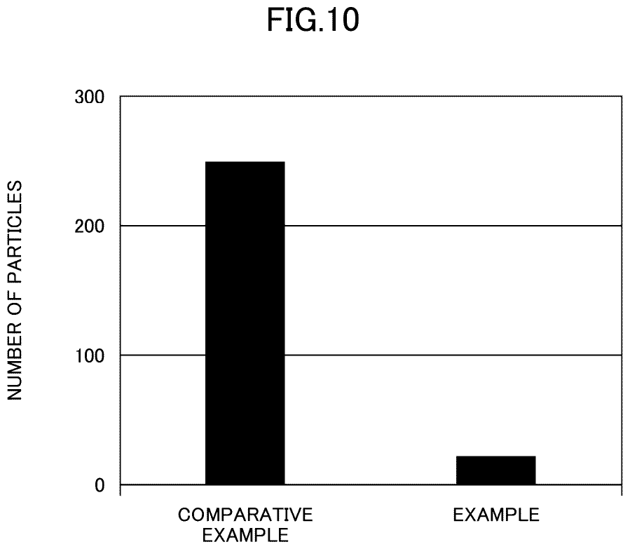

FIG. 10 is a chart illustrating the results obtained by measuring the number of particles. In FIG. 10, the left-hand bar graph indicates the number of particles in the Comparative Example, and the right-hand bar graph indicates the number of particles in the Example.

As illustrated in FIG. 10, the number of particles in the Comparative Example was 249, whereas the number of particles in the Example was 21. From the obtained results, it was demonstrated that adhesion of particles onto the substrate W was able to be suppressed by performing the film-forming process of forming a film on the substrate W placed in the recess R, while maintaining a state in which the rotation table 321 and the stage 321a were being rotated in opposite directions.

The embodiments disclosed herein should be considered to be exemplary in all respects, not to be restrictive. Omissions, substitutions, and modifications may be made in various forms to the above-described embodiments without departing from the scope and intent of the claims recited.

The above-described embodiments have been described using a case in which five stages 321a are provided in the rotation table 321. However, the present disclosure is not limited to this. For example, the number of the stages 321a may be four or less, or may be six or more.

The above-described embodiments have been described using a case in which the processor 310 includes the vacuum chamber 311, the gas inlet 312, the gas outlet 313, the transfer port 314, the heater 315, and the cooler 316. However, the present disclosure is not limited to this. For example, the processor 310 may further include a plasma generator configured to generate a plasma for activating various gases supplied into the vacuum chamber 311.

According to the present disclosure, it is possible to suppress adhesion of particles onto a substrate.

What is claimed is:

1. A substrate-processing apparatus, comprising:
a vacuum chamber;
a rotation table provided in the vacuum chamber;
a stage that is rotatable relative to the rotation table and includes a recess in which a substrate is to be placed; and
a controller including a memory and a processor connected to the memory, wherein
a rotation shaft of the stage is provided at a position that is shifted from a center of the rotation table in a radial direction of the rotation table, and
the processor is configured to perform a film-forming process of forming a film on the substrate placed in the recess, while maintaining a state in which the rotation table and the stage are being rotated in opposite directions.

2. The substrate-processing apparatus according to claim 1, wherein
the recess has an inner diameter that is larger than a diameter of the substrate.

3. The substrate-processing apparatus according to claim 1, wherein
a rotation speed of the rotation table is a speed at which the substrate placed in the recess moves relative to the recess in response to rotation of the rotation table.

4. The substrate-processing apparatus according to claim 1, wherein
a rotation speed of the stage is lower than a rotation speed of the rotation table.

5. The substrate-processing apparatus according to claim 1, wherein
the stage is provided in two or more along a circumferential direction of the rotation table.

6. The substrate-processing apparatus according to claim 1, wherein
the processor is configured not to change, during the film-forming process, a rotation direction of the rotation table and a rotation direction of the stage.

7. The substrate-processing apparatus according to claim 1, wherein
the processor is configured to change, during the film-forming process, a rotation direction of the rotation table and a rotation direction of the stage.

8. The substrate-processing apparatus according to claim 1, wherein
the processor is configured to change, during the film-forming process, a rotation speed of the stage.

9. A substrate-processing method performed with a substrate-processing apparatus that includes a vacuum chamber, a rotation table provided in the vacuum chamber, and a stage that is rotatable relative to the rotation table and includes a recess in which a substrate is to be placed, the substrate-processing method comprising:
performing a film-forming process of forming a film on the substrate placed in the recess, while maintaining a state in which the rotation table and the stage are being rotated in opposite directions.
